(19) United States
(12) Patent Application Publication
(10) Pub. No.: US 2007/0086496 A1
(43) Pub. Date: Apr. 19, 2007

(54) Semiconductor light emitting device

(75) Inventors: Akira Tanaka, Kanagawa-ken (JP); Chie Hongo, Kanagawa-ken (JP); Yoshiyuki Harada, Tokyo (JP); Hideto Sugawara, Kanagawa-ken (JP); Masaaki Onomura, Tokyo (JP); Hiroshi Katsuno, Kanagawa-ken (JP)

Correspondence Address: BANNER & WITCOFF, LTD., ATTORNEYS FOR RESERVE;ATTORNEYS FOR CLIENT NO. 000449, 001701, 1001 G STREET, N.W., 11TH FLOOR, WASHINGTON, DC, 20001-4597, US

(73) Assignee: Kabushiki Kaisha Toshiba, Minato-ku (JP)

(21) Appl. No.: 11/357,408

(22) Filed: Feb. 21, 2006

(30) Foreign Application Priority Data
Oct. 13, 2005 (JP) 2005-0299210

(51) Int. Cl. H01S 5/00

(52) U.S. Cl. 372/43.01

(57) ABSTRACT

A semiconductor light emitting device comprises: a first cladding layer made of nitride semiconductor of a first conductivity type; an active layer provided on the first cladding layer, the active layer including a first barrier layer made of nitride semiconductor, a second barrier layer made of nitride semiconductor, and a well layer made of nitride semiconductor, the well layer being provided between the first barrier layer and the second barrier layer; and a second cladding layer provided on the active layer, the second cladding layer being made of nitride semiconductor of a second conductivity type. The first and second barrier layers and the well layer contain indium. At least one of the first barrier layer and the second barrier layer has a thickness of 30 nm or more.

### CROSS-REFERENCE TO RELATED APPLICATIONS

This application is based upon and claims the benefits of priorities from the prior Japanese Patent Application No. 2005-299210, filed on Oct. 13, 2005; the entire contents of which are incorporated herein by reference.

### BACKGROUND OF THE INVENTION

Blue-violet semiconductor laser devices for the next generation DVD (Digital Versatile Disc) and white semiconductor light emitting devices for display using nitride-based semiconductor light emitting devices have rapidly expanding application areas.

In such a nitride-based semiconductor light emitting device, a single or multiple quantum well structure is used to achieve high light emission efficiency by reducing its operating current.

For example, a multiple quantum well (MQW) active layer including InGaN is used in a blue-violet semiconductor laser device for the next generation DVD that operates in the 400-nanometer wavelength band. In this case, since the active layer contains In (indium), its crystal growth is typically performed at temperatures below 1,000 degrees centigrade.

On the other hand, crystal growth for layers such as the cladding layer, optical guide layer, and contact layer is typically performed at temperatures above 1,000 degrees centigrade. Therefore crystal growth is interrupted before and after the process of forming an active layer, which involves crystal growth at a lower temperature. Crystal interface occurring after such interruption of crystal growth is prone to crystal defects, which are undesirable for the properties of semiconductor light emitting devices.

Furthermore, the MQW structure typically has thin barrier layers. Dislocations and the like from crystal defects near the interface may extend to the well layer through the barrier layers on its both sides. This may be accelerated, among others, by energization.

Moreover, the p-type overflow prevention layer provided for reducing current due to electron overflow is doped with magnesium (Mg), which may pass through the thin barrier layer. In a previously disclosed technology (JP 2004-63537A), diffusion of Mg into the well layer is prevented to reduce aging degradation rate. However, this is not sufficient for preventing aging degradation due to crystal defects.

### SUMMARY OF THE INVENTION

According to an aspect of the invention, there is provided a semiconductor light emitting device comprising: a first cladding layer made of nitride semiconductor of a first conductivity type; an active layer provided on the first cladding layer, the active layer including a first barrier layer made of nitride semiconductor, a second barrier layer made of nitride semiconductor, and a well layer made of nitride semiconductor, the well layer being provided between the first barrier layer and the second barrier layer; and a second cladding layer provided on the active layer, the second cladding layer being made of nitride semiconductor of a second conductivity type, the first and second barrier layers and the well layer containing indium, and at least one of the first barrier layer and the second barrier layer having a thickness of 30 nm or more.

According to other aspect of the invention, there is provided a semiconductor light emitting device comprising: a substrate; a first cladding layer provided on the substrate, the first cladding layer being made of an AlₛGa₁₋ₛN (0<s≦0.3) layer of a first conductivity type, or a superlattice multilayer including an AlₛGa₁₋ₛN (0<s≦0.3) layer and a GaN layer; an active layer including a first barrier layer made of In_{z}Ga_{1-z}N (0<z≦0.02) provided on the first cladding layer, a well layer made of InₓGa₁₋ₓN (0.05≦x≦1.0) provided on the first barrier layer, and a second barrier layer made of In_{y}Ga_{1-y}N (0<y≦0.02) provided on the well layer; and a second cladding layer provided on the active layer, the second cladding layer being made of an AlₜGa₁₋ₜN (0<t≦0.3) layer of a second conductivity type, or a superlattice multilayer including an AlₜGa₁₋ₜN (0<t≦0.3) layer and a GaN layer, the first barrier layer having a thickness of 30 nm or more, and the second barrier layer having a thickness of 30 nm.

According to other aspect of the invention, there is provided a semiconductor light emitting device comprising: a GaN foundation layer; an active layer including a first barrier layer made of In_{z}Ga_{1-z}N(o<z≦0.02) provided on the GaN foundation layer, a well layer made of InₓGa₁₋ₓN(0.05≦x≦1.0) provided on the first barrier layer, and a second layer made of In_{y}Ga_{1-y}N(0<y≦0.02) provided on the well layer; and a cladding layer provided on the active layer, the cladding layer being made of an AlₜGa₁₋ₜN(0<t≦0.3) layer of a second conductivity type, or a superlattice multilayer of a second conductivity type including an Al_{T}Ga₁₋ₜN(0<t≦0.3) layer and a GaN layer, at least one of the first and the second barrier layer having a thickness of 30 nm or more.

### BRIEF DESCRIPTION OF THE DRAWINGS

FIG. 1 is a schematic cross section of a nitride semiconductor laser device according to a first example of the invention;

FIG. 2 is an energy band diagram for the first example;

FIG. 3 is an energy band diagram representing an active layer composed of a quantum well structure in the first example;

FIG. 4 is a graphical diagram showing the result of an energization accelerated aging test for the first example in which the barrier layer has a thickness of 50 nm;

FIG. 5 is a graphical diagram showing the result of an energization accelerated aging test for the first example in which the barrier layer has a thickness of 30 nm;

FIG. 6 is a graphical diagram showing the result of an energization accelerated aging test for a comparative example in which the barrier layer has a thickness of 20 nm;

FIG. 7 is a graphical diagram showing growth temperatures in the crystal growth process of the present example;

FIG. 8 is a flow chart of the crystal growth method of the present example;

FIG. 9 is an energy band diagram for a nitride semiconductor laser device according to a second example of the invention;

FIG. 10 is an energy band diagram for a nitride semiconductor laser device according to a third example of the invention;

FIG. 11 is a schematic cross section of a nitride semiconductor light emitting device according to a fourth example of the invention;

FIG. 12 is an energy band diagram for the fourth example; and

FIG. 13 is a schematic cross section of a surface mounted white LED incorporating the nitride semiconductor light emitting device of the fourth example illustrated in FIG. 11.

### DETAILED DESCRIPTION OF THE INVENTION

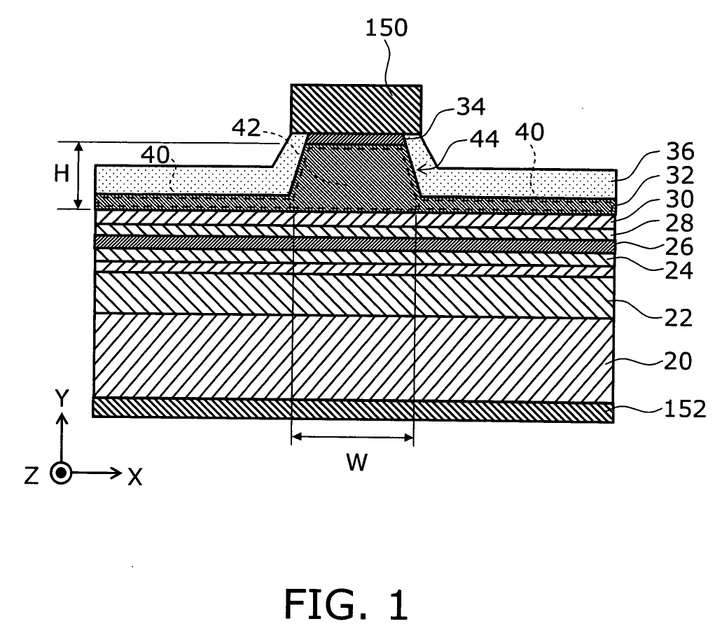

Embodiments of the invention will now be described with reference to the drawings. FIG. 1 is a schematic cross section of a nitride semiconductor laser device according to a first example of the invention. The substrate used in the first example is an n-type GaN substrate. On an n-type GaN substrate 20, an n-type Al_{0.05}Ga_{0.95}N cladding layer 22 (with a thickness of 1.5 μm), an n-type GaN optical guide layer 24 (with a thickness of 0.07 μm), and an active layer 26 are laminated.

On the active layer 26, a p⁺-type Al_{0.20}Ga_{0.80}N overflow blocking layer 28 (with a thickness of 10 nm), a p-type GaN optical guide layer 30 (with a thickness of 0.03 μm), a p-type Al_{0.05}Ga_{0.95}N cladding layer 32 (with a thickness of 0.6 μm), and a p⁺-type GaN contact layer 34 (with a thickness of 0.1 μm) are laminated. These semiconductor multilayer films can be sequentially grown on the n-type GaN substrate 20 by, for example, MOCVD (Metal Organic Chemical Vapor Deposition) method. Note that typically, Si (silicon) is used as n-type impurities and Mg (magnesium) is used as p-type impurities.

Note that the “nitride semiconductor” used herein includes semiconductors having any composition represented by the chemical formula InₓAl_{y}Ga_{1-x-y}N (0≦x≦1, 0≦y≦1, x+y≦1) where the composition ratios x and y are varied in the respective ranges. Furthermore, the “nitride semiconductor” also includes those further containing any of various impurities added for controlling conductivity types.

The structure illustrated in FIG. 1 belongs to a refractive index waveguide structure also referred to as the ridge waveguide type structure. More specifically, the p-type AlGaN cladding layer 32 has a ridge portion 42 with height H represented by dashed line and a non-ridge portion 40 also represented by dashed line. Note that in the first example, the height H of the ridge portion 42 is 0.6 μm and the height of the non-ridge portion 40 is 0.05 μm. The p⁺-type GaN contact layer 34 above the ridge portion 42 is provided selectively. An insulating film 36 is formed on the p⁺-type GaN contact layer 34 side face and a ridge side face 44 of the ridge portion 42, which are patterned. The insulating film 36 can be made of material such as silicon oxide film (SiO₂) or silicon nitride film (Si₃N₄). Note that SiO₂ has a refractive index of about 1.5, and Si₃N₄ has a refractive index of 1.9 to 2.1.

The p⁺-type GaN contact layer 34 is connected to a p-side electrode 150 made of monolayer, lamination, or alloy of Pt, Pd, Ni, or Au, for example. The n-type GaN substrate 20 is connected to an n-side electrode 152 made of monolayer, lamination, or alloy of Ti, Pt, Au, or Al. The p⁺-type GaN contact layer 34 serves to decrease contact resistance between the p-type AlGaN cladding layer 32 and the p-side electrode 150, thereby the operating voltage is decreased.

Since the insulating film 36 is provided on the ridge side face 44 of the ridge portion 42, a difference occurs between the refractive index of the p-type AlGaN cladding layer 32 constituting the ridge portion 42 and that of the insulating film 36.

Since the refractive index of the ridge portion 42 is higher than that of the insulating film 36, the fundamental horizontal transverse mode is confined horizontally (X axis) relative to the active layer 26 in the cross section orthogonal to the optical axis (parallel to the Z axis). However, if the width W of the ridge portion 42 at its bottom is too large as compared to the wavelength, higher order modes may occur in the horizontal transverse mode. Preferably, the width W of the ridge portion 42 is 1 to 3 μm. In this example, it is set to 1.5 μm. As a result, higher order modes can be suppressed.

Furthermore, a low reflection film having a reflectance of about 5% and a high reflection film having a reflectance of 95% or higher are formed, respectively, on the light extraction end face and the rear side end face, which are perpendicular to the Z axis.

Next, the function of the laminated structure will be described in more detail.

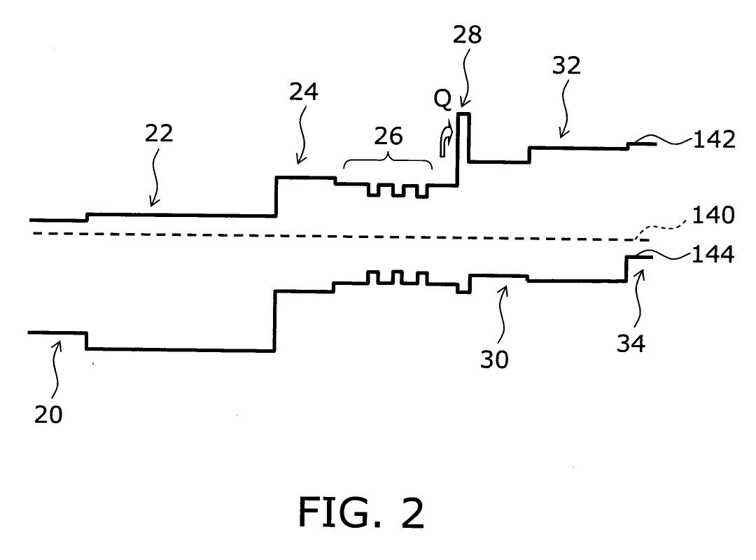

FIG. 2 is an energy band diagram of the semiconductor laminated structure of this example. The conduction band 142 and the valence band 144 in various layers are represented so as to align the quasi-Fermi level 140.

It can also be understood from FIG. 2 that the p⁺-type overflow blocking layer 28 can suppress unnecessary increase of operation current due to leakage of electrons Q, injected from the n-type GaN substrate 20 side, into the p-type Al_{0.05}Ga_{0.95}N cladding layer 32, as indicated by an arrow. More specifically, a higher Al (aluminum) composition ratio of the p⁺-type AlGaN overflow blocking layer 28 increases its band gap difference relative to the active layer 26, which can prevent electrons Q injected from the n-side from leaking from the active layer 26 into the p-type Al_{0.05}Ga_{0.95}N cladding layer 32. Preferably, the Al composition ratio is 0.20 or more.

Moreover, since the heterobarrier on the conduction band side relative to the active layer 26 can be increased by increasing the p-type concentration (e.g., 1×10^{20 cm}⁻³) of the p⁺-type AlGaN overflow blocking layer 28, the leakage of electrons Q can be further reduced. Preferably, the thickness of the p⁺-type AlGaN overflow blocking layer 28 is set to not more than 20 nm in order to avoid degradation of crystallinity.

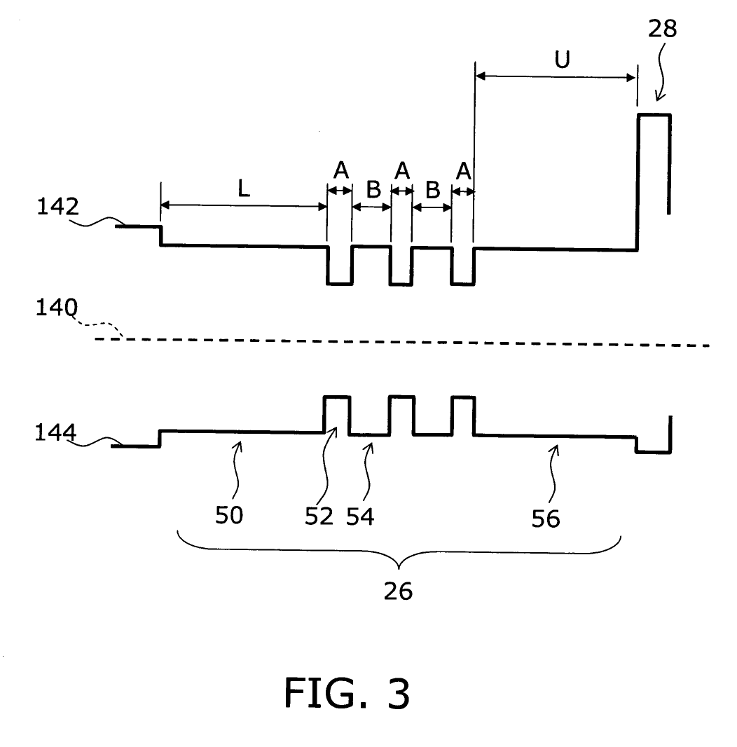

FIG. 3 is an energy band diagram for the active layer 26 of this example. The active layer 26, made of InₓGa₁₋ₓN/In_{w}Ga_{1-w}N, can be a single quantum well or multiple quantum well active layer. In this case, the In (indium) composition ratio x in a well layer 52 can be selected within the range of 0.05 to 0.2, and the In composition ratio w in the inner barrier layer 54 can be selected within the range of 0 to 0.02. The thickness of the well layer 52 can be 2 to 5 nm, the number of wells can be two to four, and the thickness of the inner barrier layer 54 can be 3 to 10 nm. In the first example, the structure of In_{0.13}Ga_{0.87}N/In_{0.01}Ga_{0.99}N is selected, and the well layer 52 has a thickness A of 3 nm, the number of wells is three, and the inner barrier layer 54 has a thickness B of 10 nm.

The lower barrier layer 50 adjacent to the n-type GaN optical guide layer 24 has a composition of In_{z}Ga_{1-z}N (0<z≦0.02) and a thickness L of 30 nm or more. The upper barrier layer 56 adjacent to the p⁺-type overflow blocking layer 28 has a composition of In_{y}Ga_{1-y}N (0<y≦0.02) and a thickness U of 30 nm or more. In the foregoing, the In composition ratio w in the inner barrier layer 54, the In composition ratio z in the lower barrier layer 50, and the In composition ratio y in the upper barrier layer 56 may be either equal or different. Equal composition ratio has the advantage of simplifying the crystal growth process.

Each of the n-type AlGaN cladding layer 22 and the p-type AlGaN cladding layer 32 may be AlₛGa₁₋ₛN (0<s≦0.3), or an alternate lamination of AlₛGa₁₋ₛN (0<s≦0.3)/GaN superlattice with a layer thickness of 1 to 5 nm. The superlattice layer has the advantage of alleviating stress distortion.

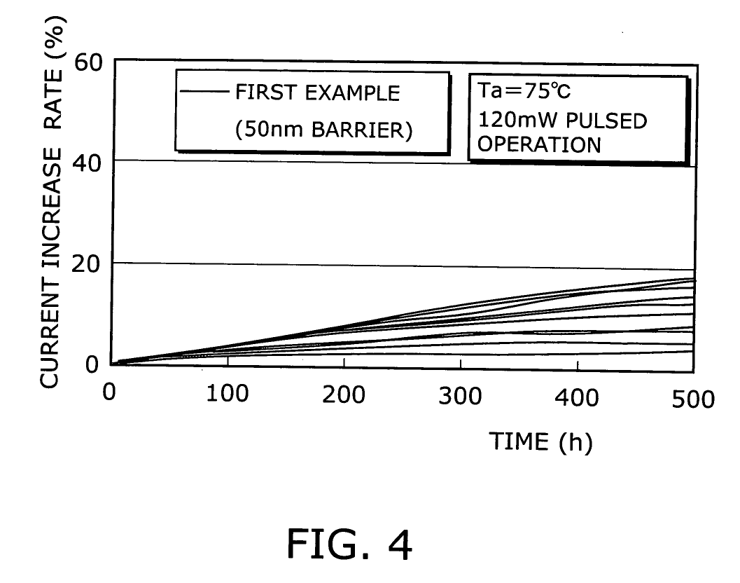

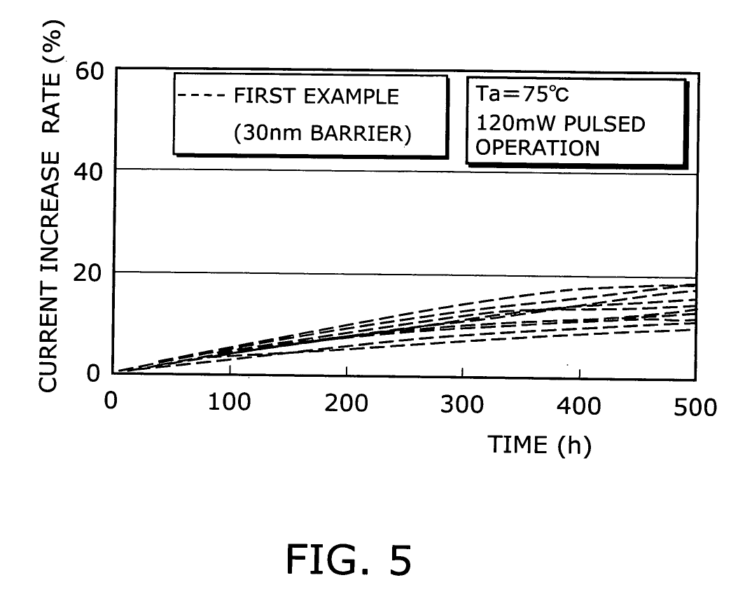

Next, an energization accelerated aging test for the first example is described. FIGS. 4 and 5 are graphical diagrams showing the rate of change of the operating current of semiconductor laser devices under pulsed operation controlled at an output of 120 mW (APC: Automatic Power Control). In both cases, the ambient temperature Ta is 75 degrees centigrade, the pulse width is 50 ns (nanoseconds), and the pulse duty ratio is 50%. Each semiconductor laser device is subjected to the energization accelerated aging test after a predetermined screening process.

FIG. 4 is a graphical diagram showing the change of operating current (by measurement) in the first example where the thickness U of the upper barrier layer and the thickness L of the lower barrier layer are both 50 nm. The number of samples is 10. With time, the operating current for obtaining a predetermined optical output (120 mW, pulsed operation) is gradually increased. After 500 hours, the current increase rate dIₒₚ/dt (mA/h) is distributed between 0 and 0.088 and averages about 0.034.

FIG. 5 is a graphical diagram showing the change of operating current (by measurement) in the first example where the thickness U of the upper barrier layer and the thickness L of the lower barrier layer are both 30 nm. The number of samples is again 10. After 500 hours, the current increase rate dIₒₚ/dt (mA/h) is distributed between 0.006 and 0.060 and averages about 0.027.

The current increase rate at 500 hours is slightly smaller for a barrier layer thickness of 30 nm. Conversely, the number of samples with a smaller change of current at 500 hours is larger for a barrier layer thickness of 50 nm.

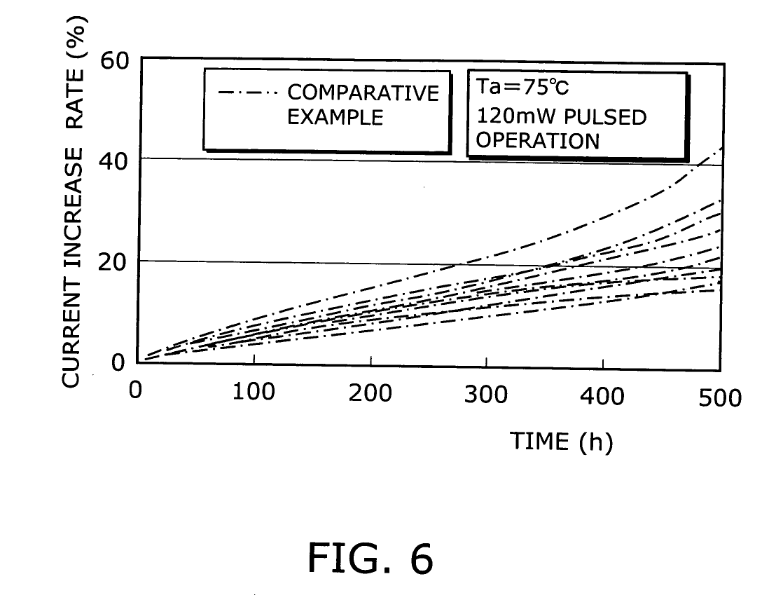

FIG. 6 is a graphical diagram showing the change of operating current (by measurement) in a comparative example where the thickness L of the lower barrier layer 50 and the thickness U of the upper barrier layer 56 are both 20 nm. In this case again, the test is performed under the condition of an ambient temperature Ta=75 degrees centigrade, a pulse output of 120 mW, a pulse width of 50 ns, and a pulse duty ratio of 50%, and samples are passed through a predetermined screening process. The comparative example exhibits a large current increase rate. After 280, 350, 355, 360, 430, and 470 hours, the current increase rate already reaches 20%. The current increase rate for the remaining samples ranges between 0.016 and 0.199 and averages about 0.100. The comparative example exhibits a current increase rate three or more times larger than that of the first example, and has few samples that become stable by saturation of operating current after 500 hours.

Next, relative comparison of average lifetime is described. For a semiconductor laser device, an energization accelerated aging test can be used to determine dIₒₚ/dt. The time at which the current increase rate exceeds a predetermined value can be regarded as “lifetime”, which can be used to determine the average lifetime. Here, the slope dIₒₚ/dt at 500 hours is used to extrapolate the plot to the time at which the operating current increase rate reaches 20%. This time is regarded as the lifetime of each sample. The average lifetime calculated from these estimated values of lifetime is referred to as MTTF (Mean Time To Failure).

The average lifetime for the comparative example is calculated from the direct “lifetime” values of the samples that have a current increase rate exceeding 20% within 500 hours, and the lifetime values estimated from the current increase rate at 500 hours.

In the first example, the average lifetime for a barrier layer thickness of 50 nm is about 4 times larger than in the comparative example at Ta=75 degrees centigrade. The average lifetime for a barrier layer thickness of 30 nm is about 3.3 times larger than in the comparative example at Ta=75 degrees centigrade.

The required average lifetime for the next generation DVD is over 2000 hours at a pulse output of 120 mW and an ambient temperature Ta=75 degrees centigrade. This average lifetime is achieved by the present example for a barrier layer thickness of 30 nm or more.

The average lifetime at an ambient temperature Ta=75 degrees centigrade has been described above. In general, the operating current increase rate of a semiconductor laser device is proportional to exp(−Ea/kT), where Ea is the activation energy (eV), k is the Boltzmann constant (8.616×10⁻⁵ eV/K), and T is the absolute temperature (K). For a nitride-based semiconductor laser device, the inventors have experimentally determined the activation energy Ea to be 0.40 eV. Accordingly, it is possible to obtain an average lifetime at room temperature 25 degrees centigrade that is about 9.4 times larger than that at Ta=75 degrees centigrade.

Next, the reason for the improvement of the operating current increase rate in this example is described. As described later in detail, the QW active layer includes a multilayer of InGaN/InGaN containing In. The growth temperature for MOCVD of a nitride-based multilayer film containing In is typically set within the range of 750 to 900 degrees centigrade because the vapor pressure of InGaN is high (In is easy to evaporate). On the other hand, the growth temperature for AlGaN-based multilayer films sandwiching the active layer is typically set within the range of 1,000 to 1,100 degrees centigrade. Such interrupted growth due to lowering and raising the temperature is likely to create crystal defects at interfaces caused by the interruption of crystallization.

Crystal defects such as dislocations that occurred at an interface between the n-type GaN optical guide layer 24 and the lower barrier layer 50 and at an interface between the p⁺-type AlGaN overflow blocking layer 28 and the upper barrier layer 56 may extend to the well layer 52. Barrier layers of 20 nm in the comparative example, or even thinner barrier layers, may be subjected to more significant degradation due to extension of dislocations and the like.

Furthermore, Mg and the like diffused from the p⁺-type AlGaN overflow blocking layer 28 may be diffused through the thin upper barrier layer 56 into the well layer 52. In this case, a deep level may be produced near the quantum well and lead to non-emissive recombinations, which accelerate energization aging.

On the contrary, in the present example, the thickness U of the upper barrier layer 56 and the thickness L of the lower barrier layer 50 are 30 nm or more. Therefore crystal defects such as dislocations that occurred at interfaces due to interruption of crystallization can be prevented from extending to the well layer 52. Likewise, diffusion of impurities such as Mg from the p⁺-type overflow blocking layer 28 can be prevented. As described above, in this example, prevention of the extension of dislocations and prevention of non-emissive recombinations allows for reducing the operating current increase during energization. As a result, the average lifetime can satisfy the specification of the next generation DVD.

The first example has been described with reference to the case where the thickness U of the upper barrier layer 56 and the thickness L of the lower barrier layer 50 are both 30 nm or more. However, the invention is not limited thereto. For example, the operating current increase can also be advantageously prevented when only the thickness U of the upper barrier layer 56, which can reduce the effect of Mg diffusion, is set to 30 nm or more. The operating current increase due to energization can be further reduced when the thickness L of the lower barrier layer 50 is also set to 30 nm or more.

Next, a crystal growth method for a nitride-based semiconductor laser device according to this example including a barrier layer thickness of 30 nm or more is described. The MOCVD method is described here by way of example. Crystal growth of InGaN film is typically performed at temperatures within the range of about 750 to 900 degrees centigrade. Because of its low growth rate, the thickness is typically set to 20 nm or less. However, the growth method described below facilitates crystal growth of an InGaN film having a thickness of 30 nm or more.

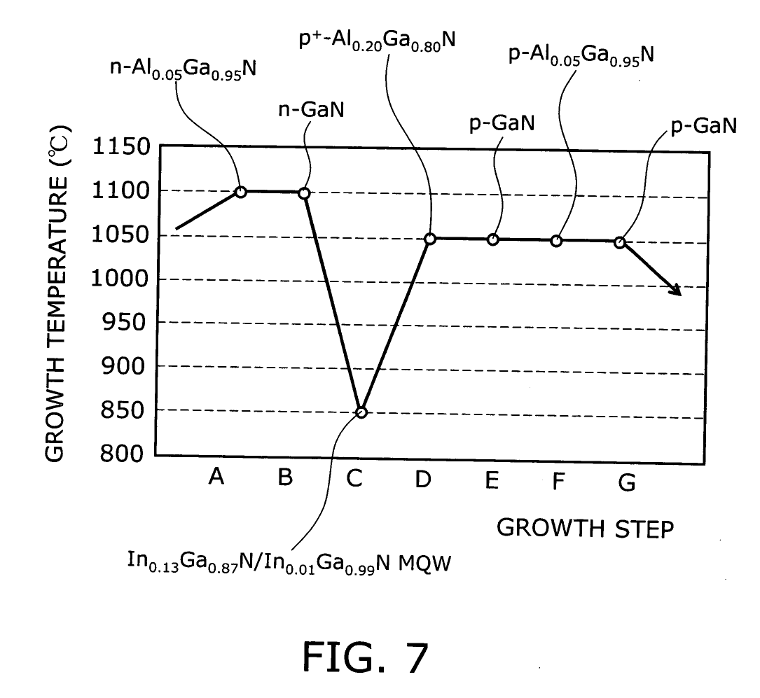

FIG. 7 is a graphical diagram showing growth temperatures in the crystal growth process of a gallium nitride based multilayer film. The horizontal axis represents the growth steps A to G for the constituent films. The vertical axis represents the growth temperature (degrees centigrade). Typically, a preferred temperature range for crystal growth of GaN and AlGaN is 1,000 to 1,100 degrees centigrade. Therefore, at steps A and B, the n-type Al_{0.05}Ga_{0.95}N cladding layer 22 and the n-type GaN optical guide layer are grown at 1,100 degrees centigrade, respectively. A preferred temperature range for crystal growth of InGaN is 750 to 900 degrees centigrade. Therefore, at step C, the QW layer of In_{0.13}Ga_{0.87}N/In_{0.01}Ga_{0.99}N is grown after the temperature is lowered to 850 degrees centigrade. While a smaller In composition ratio is advantageous to enhancing the effect of barrier layers, an In composition ratio of 0.01 to 0.02 is preferred for good crystallinity.

Subsequently, at steps D, E, F, and G, the p⁺-type Al_{0.20}Ga_{0.80}N overflow blocking layer 28, p-type GaN optical guide layer 30, p-type Al_{0.05}Ga_{0.95}N cladding layer 32, and p⁺-type GaN contact layer 34 are grown at 1,050 degrees centigrade, respectively. It is more preferable to perform crystal growth of AlGaN and GaN at steps D to G at a temperature 50 degrees centigrade lower than for steps A and B in view of maintaining good crystallinity.

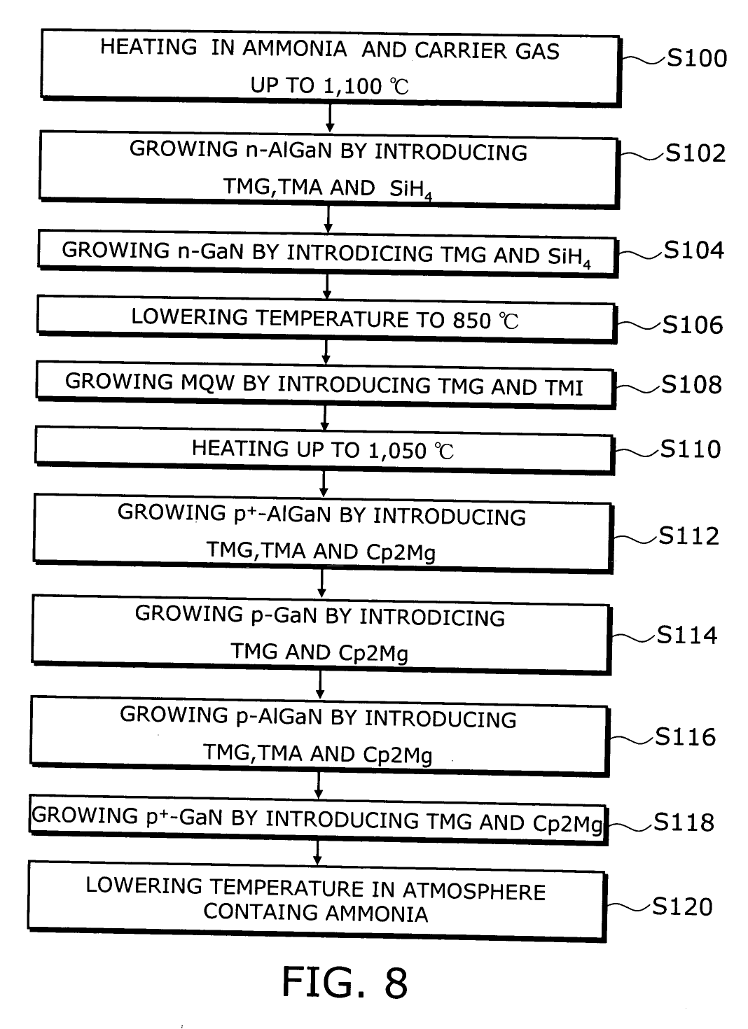

FIG. 8 is a flow chart of the crystal growth process further including description of material gases and doping gases. First, the surface of an n-type GaN substrate 20 is cleaned with solvent. The n-type GaN substrate 20 is then placed via a load-lock mechanism on a susceptor in the reaction chamber of an MOCVD apparatus.

Subsequently, the n-type GaN substrate 20 is heated to 1,100 degrees centigrade in an atmosphere of carrier gas and ammonia (S100). Growth materials, TMG (trimethyl gallium) and TMA (trimethyl aluminum), and an n-type impurity material, SiH₄, are introduced to grow an n-type Al_{0.05}Ga_{0.95}N cladding layer 22 (with a thickness of 1.5 μm) (S102). Alternatively, the n-type cladding layer may be a lamination of AlₛGa₁₋ₛN (0<s≦0.3)/GaN superlattice, which can be obtained by alternate incorporation of the step of GaN superlattice growth with the introduction of TMG and SiH₄. Subsequently, at the same temperature of 1,100 degrees centigrade, the growth material TMG and n-type impurity material SiH₄ are introduced to grow an n-type GaN optical guide layer 24 (with a thickness of 0.07 μm) (S104).

At this time the temperature is lowered to 850 degrees centigrade and stabilized (S106).

Subsequently, In_{0.13}Ga_{0.87}N/In_{0.01}Ga_{0.99}N is laminated to grow a QW active layer 26. Here, the mixing ratio of growth materials TMG and TMI (trimethyl indium) is varied to grow alternately the barrier layer In_{0.01}Ga_{0.99}N and the well layer In_{0.13}Ga_{0.87}N (S108). The lower barrier layer 50 has a thickness L of 30 or 50 nm, the well layer 52 has a thickness A of 3 nm, and the number of wells is 3. The inner barrier layer 54 between the well layers has a thickness B of 10 nm. The upper barrier layer 56 has a thickness U of 30 or 50 nm.

Subsequently, the temperature is raised to 1,050 degrees centigrade and stabilized (S110). The growth materials TMG and TMA and a p-type impurity material Cp2Mg are introduced to grow a p⁺-type overflow blocking layer 28 (with a thickness of 10 nm) (S112).

Likewise, at 1,050 degrees centigrade, the growth material TMG and impurity material Cp2Mg are introduced to grow a p-type optical guide layer 30 (with a thickness of 0.03 μm) (S114).

Subsequently, at the same temperature, the growth materials TMG and TMA and impurity material Cp2Mg are introduced to grow a p-type Al_{0.05}Ga_{0.95}N cladding layer 32 (with a thickness of 0.6 μm) (S116). Alternatively, the p-type cladding layer may be a lamination of AlₜGa₁₋ₜN (0<t≦0.3)/GaN superlattice, which can be obtained by alternate incorporation of the step of GaN superlattice growth with the introduction of TMG and SiH₄.

Finally, the growth material TMG and impurity material Cp2Mg are introduced to grow a p⁺-type GaN contact layer 34 (with a thickness of 0.1 μm) (S118), and the temperature is lowered in an atmosphere containing ammonia to complete growing a multilayer film (S120).

The growth time of the crystal growth method described above is about seven hours, which does not cause the problem of decreasing productivity for barrier layers of 30 nm or more.

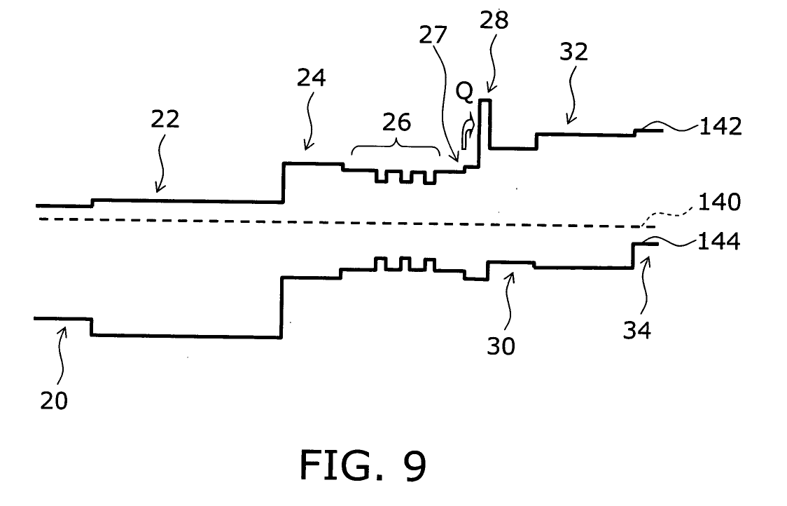

FIG. 9 is an energy band diagram representing a nitride semiconductor laser device according to a second example of the invention. Components similar to those in the first example illustrated in FIGS. 1 and 2 are marked with the same reference numerals and not described in detail. In the second example, a GaN diffusion prevention layer 27 (with a thickness of 10 nm to 0.1 μm) is provided between the upper barrier layer and the p⁺-type overflow blocking layer 28.

In general, poor crystallinity promotes diffusion of impurities. Since the p⁺-type overflow blocking layer 28 has high concentration, any crystal defects near the interface further promotes diffusion of impurities such as Mg. In this example, the GaN diffusion prevention layer 27 prevents diffusion of Mg and prevents increase of non-emissive recombinations, thereby reducing degradations such as the operating current increase.

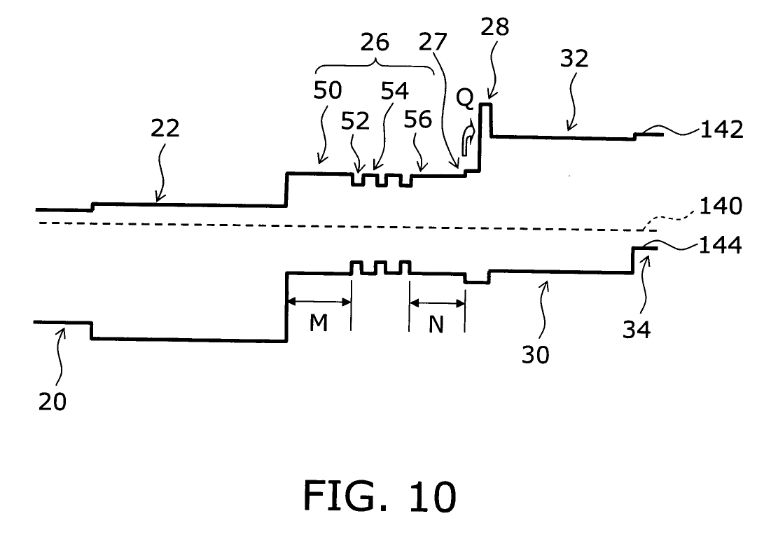

FIG. 10 is an energy band diagram representing a nitride semiconductor laser device according to a third example of the invention. Again, components similar to those in the first example illustrated in FIGS. 1 and 2 are marked with the same reference numerals and not described in detail. In the third example, the n-type and p-type optical guide layers are not provided, but the lower barrier layer 50 and the upper barrier layer 56 are provided with increased thicknesses M and N, respectively, to serve an optical guide function. In this case, the thicknesses M and N of the barrier layers may be set to 30 to 100 nm. The thickness of the optical guide layer is typically selected to range from 30 to 100 nm as illustrated in the first example, where the n-type optical guide layer 24 has a thickness of 70 nm and the p-type optical guide layer 30 has a thickness of 30 nm. Therefore, preferably, the barrier layer thickness in the third example ranges from 30 to 100 nm.

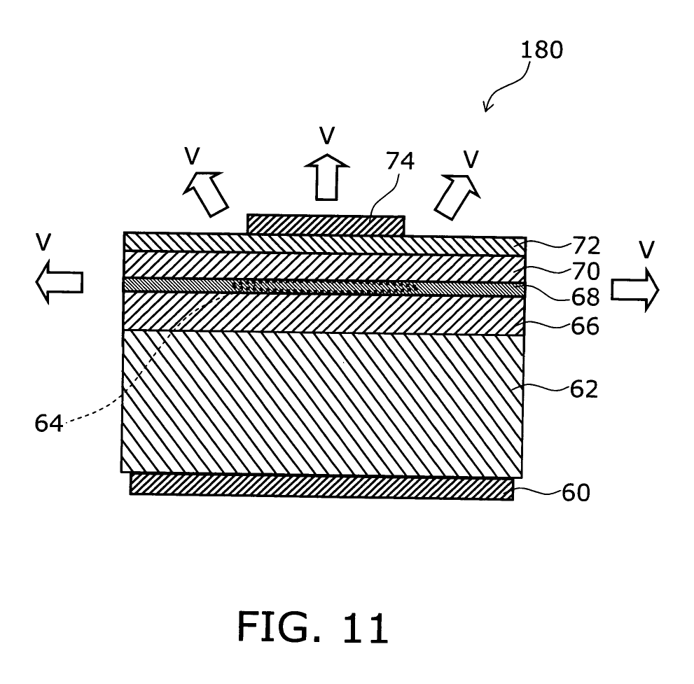

FIG. 11 is a schematic cross section of a nitride semiconductor light emitting device such as a light emitting diode (LED) according to a fourth example of the invention. On an n-type GaN substrate 62, an n-type GaN foundation layer 66 (with a film thickness of about 2 μm), an InGaN-based MQW active layer 68, a p-type AlGaN cladding layer 70 (with a film thickness of 0.5 μm), and a p-type GaN contact layer 72 (with a film thickness of 0.03 μm) are laminated in this order. Preferably, a p-side electrode 74 is made of thin film metal (conductive translucent metal) capable of transmitting light from the active layer 68. An n-side electrode 60 is formed on the rear side of the n-type GaN substrate 62.

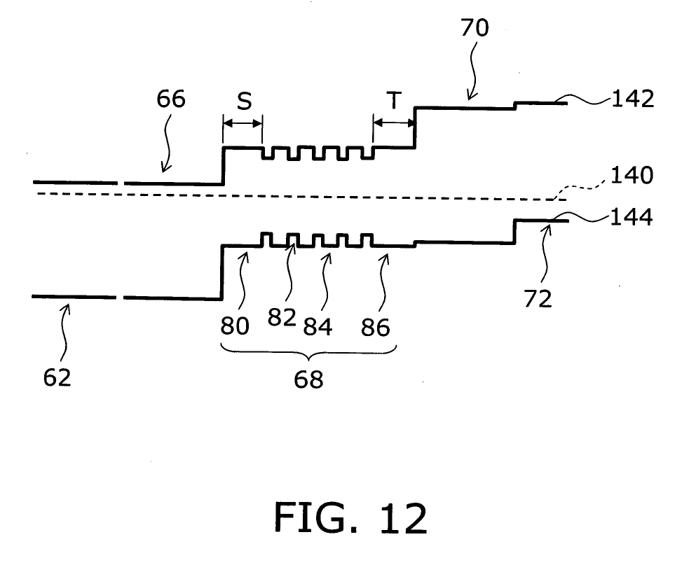

FIG. 12 is an energy band diagram for this example. The active layer 68 has five In_{0.13}Ga_{0.87}N well layers 82 (each with a thickness of 3 nm) and four In_{0.01}Ga_{0.99}N barrier layers 84 (each with a thickness of 10 nm) that are alternately laminated and combined with a lower barrier layer 80 and an upper barrier layer 86 to constitute a MQW structure. Current injected into the InGaN-based MQW active layer 68 causes radiation (radiation V) to be produced at an emission wavelength of 380 to 540 nm in an emission region 64 indicated by dashed line.

This example also involves growth interruptions because the crystal growth temperatures for the In_{0.13}Ga_{0.87}N/In_{0.01}Ga_{0.99}N MQW active layer 68 is similar to the temperatures illustrated in FIG. 7. Therefore, in order to reduce the effect of crystal defects at interfaces, the upper layer 86 has a thickness T of 30 to 100 nm, for example. This results in radiation at an emission wavelength of 380 to 540 nm with a small change of operating current. The operating current can be further reduced when the lower barrier layer 80 also has a thickness S of 30 to 100 nm. Note that the change of operating current can be reduced even when only one of the barrier layers has a thickness of 30 nm or more. It is more preferable that both the upper barrier layer 86 and the lower barrier layer 80 have a thickness of 30 nm or more to enhance the effect of reducing the change of operating current.

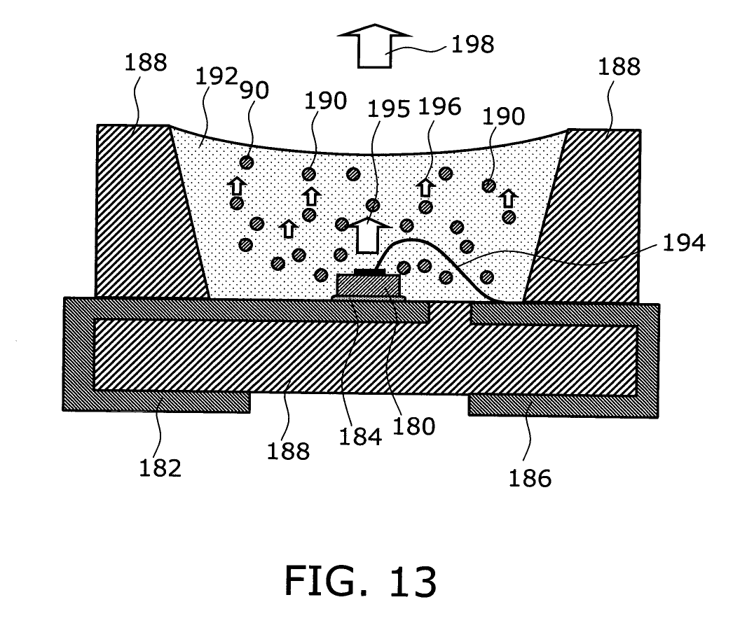

FIG. 13 is a schematic cross section of a surface mounted semiconductor light emitting device (surface mounting device, SMD) based on a semiconductor light emitting chip 180. The semiconductor light emitting chip 180 is bonded onto a first lead 182 using AuSn solder 184 or the like. An upper electrode of the semiconductor light emitting chip 180 is connected to a second lead 186 via a bonding wire 194. The first lead 182 and the second lead 186 are integrated with thermoplastic resin 188 and the like. Phosphors 190 are mixed in sealing resin 192 before heat curing.

Radiation emitted from the semiconductor light emitting chip 180 may be blue light 195 in the wavelength band of 460 to 490 nm. The phosphors 190 may be silicate-based yellow phosphors. In this situation, the phosphors 190 is excited by absorbing blue light 195 to emit wavelength-converted yellow light 196. Mixture of blue light 195 and yellow light 196 produces white light 198. A white semiconductor light emitting device obtained in this manner, in which the effect of crystal defects at interfaces is reduced, has a small change of operating current and is highly reliable for use in display backlight, illumination, and the like.

In the foregoing, examples have been described with reference to gallium nitride based semiconductors. However, the invention is not limited thereto, but is applicable to compound semiconductors. Furthermore, the crystal substrate is not limited to GaN, but can be made of sapphire, silicon carbide (SiC), and the like.

Embodiments of the invention have been described with reference to examples. However, the invention is not limited thereto. Any shape, size, material, and arrangement of various elements including the semiconductor multilayer film, ridge waveguide, phosphors, and package constituting the nitride-based semiconductor light emitting device and any step of the crystal growth process that are variously adapted by those skilled in the art are also encompassed within the scope of the invention as long as they include the features of the invention.

In addition, there may be provided a method of manufacturing a semiconductor light emitting device, the method comprising:growing a first cladding layer made of nitride semiconductor of a first conductivity type on a substrate; growing an active layer on the first cladding layer, the active layer including at least a first barrier layer made of nitride semiconductor, a well layer made of nitride semiconductor, and a second barrier layer made of nitride semiconductor; and growing a second cladding layer made of nitride semiconductor of a second conductivity type on the active layer, at least one of the first barrier layer and the second barrier layer being formed with a thickness of 30 nanometers or more, and growing the active layer is performed at a growth temperature that is lower than a growth temperature at which one of growing the first and second cladding layers is performed, the one growing the cladding layer adjacent to one of the first and second barrier layers.

In the above-described method, the first barrier layer may be formed with a thickness of 30 nanometers or more, the second barrier layer may be formed with a thickness of 30 nanometers or more, the growth temperature in the growing the active layer may be lower than the growth temperature in the growing the first cladding layer, and the growth temperature in the growing the active layer may be lower than the growth temperature in the growing the second cladding layer.

The above-described method may further comprises: growing a first optical guide layer made of nitride semiconductor on the first cladding layer, and growing a second optical guide layer made of nitride semiconductor on the active layer, the growth temperature in the growing the active layer may be lower than the growth temperature in the growing the first optical guide layer, and the growth temperature in the growing the active layer may be lower than the growth temperature in the growing the second optical layer.

In the above-described method, the growth temperature in the growing the active layer may be lower than 1,000 degrees centigrade, the growth temperature in the growing the first cladding layer may be higher than 1,000 degrees centigrade, and the growth temperature in the growing the second cladding layer may be higher than 1,000 degrees centigrade.

1. A semiconductor light emitting device comprising:
a first cladding layer made of nitride semiconductor of a first conductivity type;
an active layer provided on the first cladding layer, the active layer including a first barrier layer made of nitride semiconductor, a second barrier layer made of nitride semiconductor, and a well layer made of nitride semiconductor, the well layer being provided between the first barrier layer and the second barrier layer; and
a second cladding layer provided on the active layer, the second cladding layer being made of nitride semiconductor of a second conductivity type,
the first and second barrier layers and the well layer containing indium, and
at least one of the first barrier layer and the second barrier layer having a thickness of 30 nm or more.

2. A semiconductor light emitting device of claim 1, wherein the active layer has a multiple quantum well further including two or more of the well layers and one or more inner barrier layers provided between the two or more well layers, and the inner barrier layer contains indium.

3. A semiconductor light emitting device of claim 1, wherein the one of the first barrier layer and the second barrier layer has a thickness of 100 nm or less.

4. A semiconductor light emitting device of claim 1, wherein another of the first barrier layer and the second barrier layer has a thickness of 30 nm or more.

5. A semiconductor light emitting device of claim 4, wherein the active layer has a multiple quantum well further including two or more of the well layers and one or more inner barrier layers provided between the two or more well layers, and the inner barrier layer contains indium.

6. A semiconductor light emitting device of claim 4, wherein the first barrier layer has a thickness of 100 nm or less, and the second barrier layer has a thickness of 100 nm or less.

7. A semiconductor light emitting device of claim 1, wherein the second cladding layer is made of an AlₛGa₁₋ₛN (0<s≦0.3) layer, or a superlattice multilayer including an AlₛGa₁₋ₛN (0<s≦0.3) layer and a GaN layer, the well layer is made of InₓGa₁₋ₓN (0.05≦x≦1.0), the first barrier layer is made of In_{y}Ga_{1-y}N (0<y≦0.02), and the second barrier layer is made of In_{z}Ga_{1-z}N (0<z≦0.02).

8. A semiconductor light emitting device of claim 1, wherein the first cladding layer, the active layer and the second cladding layer are provided on a GaN substrate.

9. A semiconductor light emitting device of claim 1, further comprising:
an overflow blocking layer having a wider band gap energy than the active layer and provided between the second cladding layer and the active layer,
the overflow blocking layer being provided adjacent to the second cladding layer.

10. A semiconductor light emitting device comprising:
a substrate;
a first cladding layer provided on the substrate, the first cladding layer being made of an AlₛGa₁₋ₛN (0<s≦0.3) layer of a first conductivity type, or a superlattice multilayer including an AlₛGa₁₋ₛN (0<s≦0.3) layer and a GaN layer;
an active layer including a first barrier layer made of In_{z}Ga_{1-z}N (0<z≦0.02) provided on the first cladding layer, a well layer made of InₓGa₁₋ₓN (0.05≦x≦1.0) provided on the first barrier layer, and a second barrier layer made of In_{y}Ga_{1-y}N (0<y≦0.02) provided on the well layer; and
a second cladding layer provided on the active layer, the second cladding layer being made of an AlₜGa₁₋ₜN (0<t≦0.3) layer of a second conductivity type, or a superlattice multilayer including an AlₜGa₁₋ₜN (0<t≦0.3) layer and a GaN layer,
the first barrier layer having a thickness of 30 nm or more, and
the second barrier layer having a thickness of 30 nm or more.

11. A semiconductor light emitting device of claim 10, wherein the substrate is made of GaN.

12. A semiconductor light emitting device of claim 10, wherein the first barrier layer has a thickness of 100 nm or less, and the second barrier layer has a thickness of 100 nm or less.

13. A semiconductor light emitting device of claim 10, wherein the active layer has a multiple quantum well further including two or more of the well layers and one or more inner barrier layers provided between the two or more well layers, the inner barrier layer is made of In_{w}Ga_{1-w}N (0<w≦0.02), and light emission produced in the active layer causes lasing.

14. A semiconductor light emitting device of claim 10, further comprising:
a first optical guide layer made of GaN provided between the first cladding layer and the first barrier layer, and
a second optical guide layer made of GaN provided between the second cladding layer and the second barrier layer.

15. A semiconductor light emitting device of claim 14, wherein light emission produced in the active layer causes lasing.

16. A semiconductor light emitting device of claim 10, further comprising:
an overflow blocking layer made of an AlᵣGa₁₋ᵣN(0.2≦r<1.0) and provided between the second cladding layer and the active layer,
the overflow blocking layer being provided adjacent to the second cladding layer.

17. A semiconductor light emitting device of claim 16, wherein the overflow blocking layer has the second conductivity type and an impurity concentration higher than 1×10²⁰ cm⁻³.

18. A semiconductor light emitting device comprising:
a GaN foundation layer of a first conductivity type;
an active layer including a first barrier layer made of In_{z}Ga_{1-z}N(0<z≦0.02) provided on the GaN foundation layer, a well layer made of InₓGa₁₋ₓN(0.05≦x≦1.0) provided on the first barrier layer, and a second barrier layer made of In_{y}Ga_{1-y}N(0<y≦0.02) provided on the well layer; and
a cladding layer provided on the active layer, the cladding layer being made of an AlₜGa₁₋ₜN(0<t≦0.3) layer of a second conductivity type, or a superlattice multilayer of a second conductivity type including an AlₜGa₁₋ₜN(0<t≦0.3) layer and a GaN layer,
at least one of the first barrier layer and the second barrier layer having a thickness of 30 nm or more.

19. A semiconductor light emitting device of claim 18, wherein the one of the first barrier layer and the second barrier layer has a thickness of 100 nm or less.

20. A semiconductor light emitting device of claim 18, wherein the active layer has a multiple quantum well further including two or more of the well layers and one or more inner barrier layers provided between the two or more well layers, and the inner barrier layer is made of In_{w}Ga_{1-w}N(0<w≦0.02).
